(19) United States
(12) Patent Application Publication
(10) Pub. No.: US 2026/0185231 A1
(43) Pub. Date: Jul. 2, 2026

(54) METHODS AND APPARATUS FOR CHEMICAL DELIVERY

(71) Applicant: ASM IP Holding B.V., Almere (NL)

(72) Inventor: Jad Yaacoub, Mesa, AZ (US)

(21) Appl. No.: 19/434,146

(22) Filed: Dec. 29, 2025

Related U.S. Application Data
(60) Provisional application No. 63/740,416, filed on Dec. 31, 2024.

(51) Int. Cl. C23C 16/455

(52) U.S. Cl. CPC C23C 16/45561

(57) ABSTRACT

Various embodiments of the present technology may provide an apparatus for chemical delivery that includes a transport tube comprising a domed region coupled to an end of a hollow cylinder; a first inlet coupled to and in fluid communication with the transport tube; a second inlet coupled to and in fluid communication with the transport tube; and a third inlet coupled to and in fluid communication with the transport tube; wherein the first, second and third inlets are arranged along a shared plane.

### CROSS-REFERENCE TO RELATED APPLICATIONS

This application is a nonprovisional of, and claims priority to and the benefit of, U.S. Provisional Ser. No. 63/740,416 , filed Dec. 31, 2024 and entitled “METHODS AND APPARATUS FOR CHEMICAL DELIVERY,” which is hereby incorporated by reference herein.

### FIELD OF INVENTION

The present disclosure generally relates to a method and apparatus for chemical delivery. More particularly, the present disclosure relates to flowing vapors from multiple vessels to a reaction chamber via a manifold having separate inlets that allow the vapors from each vessel to be isolated from each other.

### BACKGROUND OF THE TECHNOLOGY

Some semiconductor manufacturing systems have a manifold to deliver chemistry to a reaction chamber. In some cases, multiple chemistries, which are incompatible with each other, are required to pass through a common manifold.

### SUMMARY OF THE INVENTION

Various embodiments of the present technology may provide an apparatus for chemical delivery that includes a transport tube comprising a domed region coupled to an end of a hollow cylinder; a first inlet coupled to and in fluid communication with the transport tube; a second inlet coupled to and in fluid communication with the transport tube; and a third inlet coupled to and in fluid communication with the transport tube; wherein the first, second and third inlets are arranged along a shared plane.

According to one aspect, an apparatus comprises: a transport tube comprising a domed region coupled to an end of a hollow cylinder; a first inlet coupled to and in fluid communication with the transport tube; a second inlet coupled to and in fluid communication with the transport tube; and a third inlet coupled to and in fluid communication with the transport tube; wherein the first, second and third inlets are arranged along a shared plane.

In one embodiment of the above apparatus, the first inlet is angled with respect to the shared plane.

In one embodiment of the above apparatus, the first inlet is in parallel with the shared plane.

In one embodiment of the above apparatus, the second inlet is angled with respect to the shared plane.

In one embodiment of the above apparatus, the second inlet is in parallel with the shared plane.

In one embodiment of the above apparatus, the third inlet is angled with respect to the shared plane.

In one embodiment of the above apparatus, the third inlet is in parallel with the shared plane.

In one embodiment of the above apparatus, the first, second, and third inlets are arranged around hollow cylinder at different angles with respect to each other.

In one embodiment of the above apparatus, the first and second inlets are arranged 90 degrees from each other.

In one embodiment of the above apparatus, the first and third inlets are arranged at 135 degrees from each other.

In one embodiment of the above apparatus, the first, second, and third inlets are arranged below the domed region.

In yet another aspect, an apparatus, comprises: a transport tube comprising a domed region coupled to an end of a hollow cylinder; a first inlet coupled to and in fluid communication with the transport tube and angled upwards toward the domed region; a second inlet coupled to and in fluid communication with the transport tube and angled upwards toward the domed region; and a third inlet coupled to and in fluid communication with the transport tube and angled upwards toward the domed region; wherein the first, second, and third inlets are arranged around the transport tube at different angles with respect to each other.

In one embodiment of the above apparatus, the first, second and third inlets are arranged along a shared plane.

In one embodiment of the above apparatus, the first and second inlets are arranged 90 degrees from each other; and the first and third inlets are arranged at 135 degrees from each other.

In one embodiment of the above apparatus, the second and third inlets are arranged at 135 degrees from each other.

In yet another aspect, a system comprises: a reaction chamber; a manifold in fluid communication with and upstream from the reaction chamber, and comprising: a transport tube comprising a domed region coupled to a first end of hollow cylinder; a first inlet coupled to and in fluid communication with the transport tube; a second inlet coupled to and in fluid communication with the transport tube; and a third inlet coupled to and in fluid communication with the transport tube; wherein the first, second, and third inlets are disposed below the domed region and are arranged around the hollow cylinder at different angles with respect to each other.

In one embodiment of the above system, the first and second inlets are arranged 90 degrees from each other; and the first and third inlets are arranged at 135 degrees from each other.

In one embodiment of the above system, the second and third inlets are arranged at 135 degrees from each other.

In one embodiment of the above system, each of the first, second, and third inlets are angled upwards toward the domed region.

In one embodiment of the above system, the first, second and third inlets are arranged along a shared plane.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a system in accordance with embodiments of the present technology;

FIG. 2 is a cross-sectional view of a manifold in accordance with embodiments of the present technology;

FIG. 3 is a cross-sectional view of the manifold in accordance with embodiments of the present technology; and

FIG. 4 is a top view of the manifold in accordance with embodiments of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various gas lines, valves, controllers, reaction chambers, vessels, and susceptors.

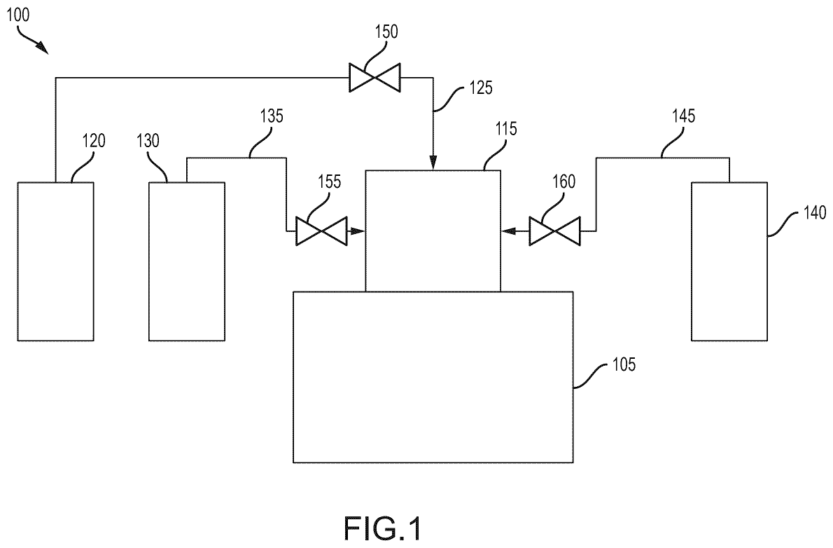

Referring to FIG. 1, an exemplary system 100 may comprise a reaction chamber 105 configured to perform processing on an object to be processed, such as a substrate (e.g., a wafer). For example, the reaction chamber 105 may be configured to perform heating, deposition, etching, polishing, ion implantation, and/or other processing on the object to be processed. In some embodiments, the reaction chamber 105 may be configured to perform a movement function, a vacuum sealing function, and an exhaust function. In some embodiments, the reaction chamber 105 may perform various semiconductor manufacturing processes, such as an atomic layer deposition (ALD) process or a chemical vapor deposition (CVD) process.

In various embodiments, the system 100 may further comprise a gas distribution system for delivering a vapor into the reaction chamber 105. In an exemplary embodiment, the gas distribution system may comprise a manifold 115 in fluid communication with the reaction chamber 105. The gas distribution system may further comprise a plurality of gas lines coupled to the manifold 115. For example, the plurality of gas lines may comprise a first gas line 125, a second gas line 135, and a third gas line 145.

In various embodiments, the system 100 may further comprise a first vessel 120 configured to contain a chemical (i.e., a precursor). The first vessel 120 may be configured to hold a solid or a liquid chemical, and may further be configured to transform the solid or liquid into a vapor. The first vessel 120 may be fluidly coupled to the manifold 115 and reaction chamber 105 via the first gas line 125.

The system 100 may further comprise a second vessel 130 configured to contain a chemical (i.e., a precursor). The second vessel 130 may be configured to hold a solid or a liquid chemical, and may further be configured to transform the solid or liquid into a vapor. The second vessel 130 may be fluidly coupled to the manifold 115 and reaction chamber 105 via the second gas line 135.

The system 100 may further comprise a third vessel 140 configured to contain a chemical (i.e., a precursor). The third vessel 140 may be configured to hold a solid or a liquid chemical, and may further be configured to transform the solid or liquid into a vapor. The third vessel 140 may be fluidly coupled to the manifold 115 and reaction chamber 105 via the third gas line 145.

In various embodiments, each of the vessels 120, 130, 140 may contain a different chemical. In addition, one vessel may contain an inert gas, such as argon or nitrogen. In some cases, two of the vessels may contain chemicals that the incompatible with each other or may cause a safety issue if exposed to each other. Accordingly, the gas lines delivering the various chemicals to the manifold 115 are separated and isolated from each other.

In various embodiments, the gas distribution system may further comprise a plurality of valves, such as a first valve 150, a second valve 155, and a third valve 160. The first valve 150 may be disposed within the first gas line 125 between the first vessel 120 and the manifold 115. The second valve 155 may be disposed between the second vessel 130 and the manifold 115. The third valve 160 may be disposed between the third vessel 140 and the manifold 115. The valves 150, 155, 160 may be communicatively coupled to and responsive to a controller (not shown), that operates (turns ON and OFF) the valves.

Referring to FIG. 1 to FIG. 4, the manifold 115 may comprise a transport tube 200. The transport tube 200 may be shaped as a hollow cylinder comprising a sidewall 230, a first open end coupled to the reaction chamber 105, and an opposing second end. The manifold 115 may further comprise a domed region 205 coupled to and disposed at the second end of the transport tube 200. The domed region 205 may prevent chemistry from accumulating at the end of the transport tube 200.

The manifold 115 may further comprise a plurality of inlets coupled to and in fluid communication with the transport tube 200. For example, the plurality of inlets may comprise a first inlet 210, a second inlet 211, and a third inlet 212. The first inlet 210 may comprise a first opening 215(a) coupled to the first gas line 125 and a second opening 215(b) in fluid communication with the transport tube 200. The second inlet 211 may comprise a first opening 220(a) coupled to the second gas line 135 and a second opening 220(b) in fluid communication with the transport tube 200. The third inlet 212 may comprise a first opening 225(a) coupled to the third gas line 145 and a second opening 225(b) in fluid communication with the transport tube 200.

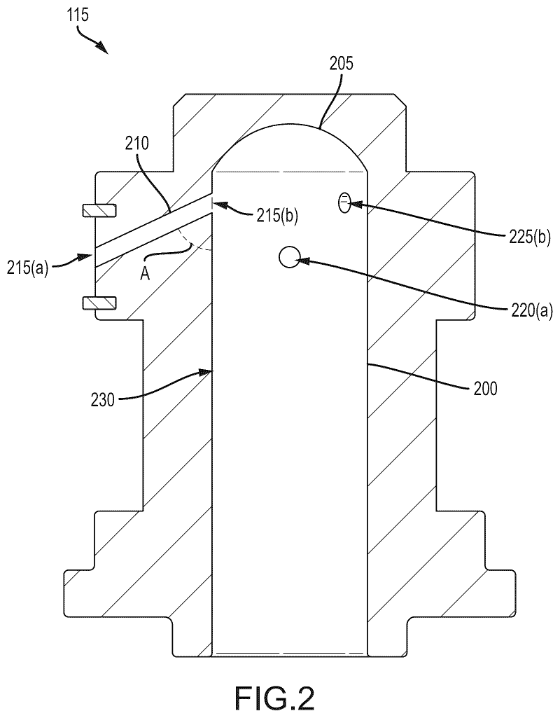

In one embodiment, and referring to FIG. 2, the first, second and third inlets 210, 211, 212 may be angled with respect to the sidewall 230 of the transport tube 200. For example, the first, second and third inlets 210, 211, 212 may be angled upwards, such that an angle A between the inlet and the sidewall 230 is less than 90 degrees.

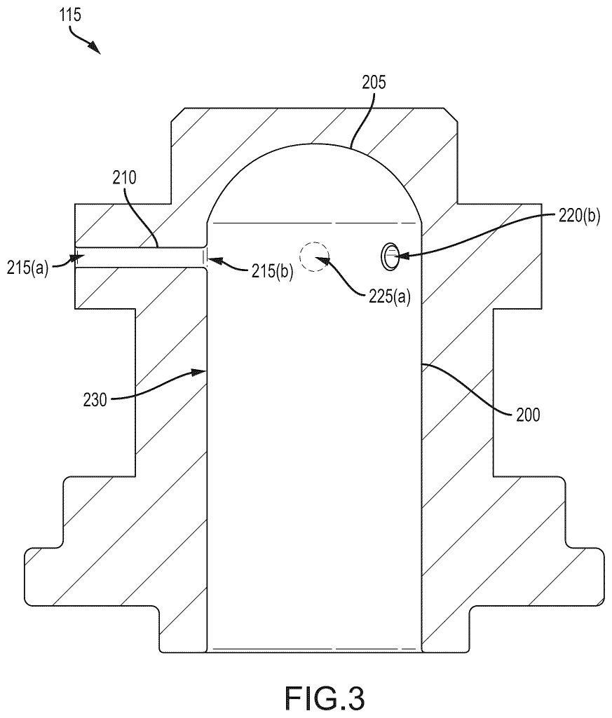

In another embodiment, and referring to FIG. 3, the first, second and third inlets 210, 211, 212 may be perpendicular to the sidewall 230 of the transport tube 200. In other words, at a 90 degree angle from the sidewall 230.

In various embodiments, and referring back to FIG. 2 to FIG. 4, the second openings 215(b), 220(b), 225(b) of each respective inlet 210, 211, 212 may be arranged below the domed region 205. In various embodiments, the second openings 215(b), 220(b), 225(b) are arranged along a shared imaginary plane. In other words, the second openings 215(b), 220(b), 225(b) are disposed at a same height along the transport tube 200.

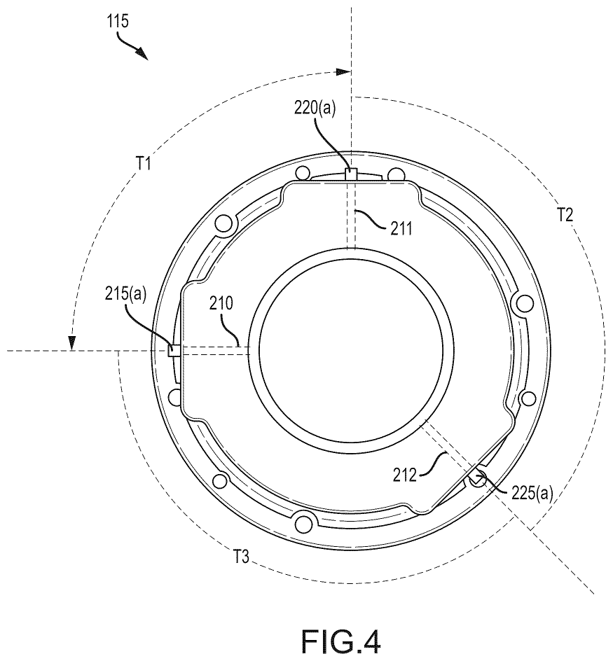

In various embodiments, and referring to FIG. 4, the first openings 215(a), 220(a), 225(a), may be arranged a different angles from each other. For example, in an exemplary embodiment, two of the openings, for example openings 215(a) and 220(a) are arranged at a first angle T1 from each other. In addition, two of the openings, for example openings 220(a) and 225(a), may be arranged a second angle T2 from each other, and two of the openings, for example openings 215(a) and 225(a), may be arranged at a third angle T3 from each other. In some embodiments, the first angle T1 is 90 degrees and the second and third angles T2, T3 are 135 degrees.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. An apparatus, comprising:
a transport tube comprising a domed region coupled to an end of a hollow cylinder;
a first inlet coupled to and in fluid communication with the transport tube;
a second inlet coupled to and in fluid communication with the transport tube; and
a third inlet coupled to and in fluid communication with the transport tube;
wherein the first, second and third inlets are arranged along a shared plane.

2. The apparatus according to claim 1, wherein the first inlet is angled with respect to the shared plane.

3. The apparatus according to claim 1, wherein the first inlet is in parallel with the shared plane.

4. The apparatus according to claim 1, wherein the second inlet is angled with respect to the shared plane.

5. The apparatus according to claim 1, wherein the second inlet is in parallel with the shared plane.

6. The apparatus according to claim 1, wherein the third inlet is angled with respect to the shared plane.

7. The apparatus according to claim 1, wherein the third inlet is in parallel with the shared plane.

8. The apparatus according to claim 1, wherein the first, second, and third inlets are arranged around hollow cylinder at different angles with respect to each other.

9. The apparatus according to claim 1, wherein the first and second inlets are arranged 90 degrees from each other.

10. The apparatus according claim 1, wherein the first and third inlets are arranged at 135 degrees from each other.

11. The apparatus according to claim 1, wherein the first, second, and third inlets are arranged below the domed region.

12. An apparatus, comprising:
a transport tube comprising a domed region coupled to an end of a hollow cylinder;
a first inlet coupled to and in fluid communication with the transport tube and angled upwards toward the domed region;
a second inlet coupled to and in fluid communication with the transport tube and angled upwards toward the domed region; and
a third inlet coupled to and in fluid communication with the transport tube and angled upwards toward the domed region;
wherein the first, second, and third inlets are arranged around the transport tube at different angles with respect to each other.

13. The apparatus according to claim 12, wherein the first, second and third inlets are arranged along a shared plane.

14. The apparatus according to claim 12, wherein: the first and second inlets are arranged 90 degrees from each other; and the first and third inlets are arranged at 135 degrees from each other.

15. The apparatus according to claim 14, wherein the second and third inlets are arranged at 135 degrees from each other.

16. A system, comprising:
a reaction chamber;
a manifold in fluid communication with and upstream from the reaction chamber, and comprising:
a transport tube comprising a domed region coupled to a first end of a hollow cylinder;
a first inlet coupled to and in fluid communication with the transport tube;
a second inlet coupled to and in fluid communication with the transport tube; and
a third inlet coupled to and in fluid communication with the transport tube;
wherein the first, second, and third inlets are disposed below the domed region and are arranged around the hollow cylinder at different angles with respect to each other.

17. The system according to claim 16, wherein: the first and second inlets are arranged 90 degrees from each other; and the first and third inlets are arranged at 135 degrees from each other.

18. The system according to claim 17, wherein the second and third inlets are arranged at 135 degrees from each other.

19. The system according to claim 16, wherein each of the first, second, and third inlets are angled upwards toward the domed region.

20. The system according to claim 16, wherein the first, second and third inlets are arranged along a shared plane.
